(19) United States
(12) Patent Application Publication
(10) Pub. No.: US 2025/0123162 A1
(43) Pub. Date: Apr. 17, 2025

(54) METHOD FOR INSTALLING AND OPERATING A MEASURING ASSEMBLY WITH SPATIALLY WIDELY DISTRIBUTED SENSOR MEASURING POINTS

(71) Applicant: HOTTINGER BRÜEL & KJAER GMBH, 64293 Darmstadt (DE)

(72) Inventors: Marco M Schäck, Rödemark (DE); MICHAEL DÖRFEL, Griesheim (DE); SANDRO DI NATALE, Mannheim (DE); DMITRI TCHERNIAK, Humlebaek (DK); GIANMARCO SIRONI, Bensheim (DE)

(73) Assignee: HOTTINGER BRÜEL & KJAER GMBH, 64293 Darmstadt (DE)

(21) Appl. No.: 18/568,531

(22) PCT Filed: Jun. 3, 2022
(86) PCT No.: PCT/DE2022/000060

§ 371 Date: Dec. 8, 2023

(30) Foreign Application Priority Data
Jun. 11, 2021 (DE) 10 2021 003 016.8

(51) Int. Cl. G01L 1/20; G01K 1/14; G01K 7/02; G01L 1/22; G01M 5/00

(52) U.S. Cl. CPC G01L 1/205; G01K 1/14; G01K 7/02; G01L 1/2206; G01M 5/0008

(57) ABSTRACT

In a method for installing and operating a measuring assembly, sensors are attached to a measurement object and measuring cables are connected to the sensors and connected to measuring amplifier channels of a measuring amplifier. After checking connection of the measuring cables and whether the measuring amplifier indicates a measuring signal for each of the measuring amplifier channels, parameterization data are acquired from a data sheet for each sensor and fed into a measuring cable end to which the sensor is connected or directly into the sensor. When the measuring channels have received the measuring signals, the measuring amplifier generates a confirmation signal and confirms a proper parametrization of the sensor.

The invention relates to a method for the installation and operation of a measuring assembly with a multitude of sensor measuring points that are spatially widely distributed. By the expression “spatially widely distributed” the following is to be understood: In order to measure, e.g., forces or temperatures or other measured variables on large objects, sensors have to be attached to these objects at many locations. Such objects are, e.g., buildings, bridges, cranes or also airplanes. Measurement is particularly complicated on bridges that are several kilometers long, because several thousand sensors sometimes have to be attached there. Each sensor is connected to an electrical cable. The cables are combined into cable bundles and routed to the measuring amplifiers. The measuring amplifiers are located at a central place.

A typical application is the measurement of forces and strains using so-called strain gauges or the measurement of temperature using a thermocouple.

To measure forces on bridge structures, the force sensors—preferably so-called strain gauges—are attached at the points where the strain is to be measured. The same applies to temperature sensors when temperatures or temperature differences are to be measured.

In the following, reference is made only to sensors and this refers to sensors for various measured variables, preferably strain gauges however.

Specific to the measurement task at hand is the requirement that each measuring point has to be connected to a separate measuring channel of a measuring device. When, e.g., a railroad bridge has several thousand measuring points, total installation costs are very high.

After Installation of all sensors, each sensor or the associated measuring cable must be associated to the correct measuring channel of the measuring amplifier. In other words, a meaningful measurement is only possible when it is known which measuring channel belongs to which measuring point.

Association of a measuring channel to a certain measuring point is trivial when only a few measuring points and short measuring cables are involved. In such a case, the measuring technician can visually follow the course of the measurement cable from the measurement point to the input of the measurement amplifier channel. However, when the measuring cables on a railroad bridge are several hundred kilometers long, the respective cable ends must be determined using complex electrical continuity tests or markings. Mix-ups may already occur hereby, i.e. a measuring cable may inadvertently be connected to the wrong measuring channel.

To solve this problem, a solution using identification tags is proposed in document JP 2004-294 382 A, but this is complex and cost-intensive.

Such measurements are usually performed only once or at long intervals. After each measurement, the sensors are usually removed again. Therefore, there is also great interest in reducing the effort for the installation of the measuring assembly. The possible mix-up of the measuring cables when connecting them to the measuring amplifier channels is, however, only a first source of error.

However, there is still a second source of error:

Each sensor, preferably from the group of strain gauges or temperature sensors, has particular electrical properties that differ from sensor to sensor. These properties are called parameters.

These parameters are known and must be set on the measuring amplifier in order to achieve an optimum measurement result. When, e.g., a strain gauge sensor has 4 parameters, these 4 parameters must be set by hand on the measuring amplifier. The parameters are set using rotary knobs or keys on the measuring amplifier. Only a single incorrectly entered parameter leads to an incorrect measurement result. Thus, the greater the number of parameters, the greater the risk of error, even when only a few measuring points or a few sensors are involved.

With, e.g., 500 measuring points and 4 parameters, the measuring technician would have to manually make 2000 parameter settings. It is therefore obvious that even with the highest mental concentration of the measuring technicians who carry out the parameterization, incorrect settings can occur, rendering the measurement result unusable. With 5000 measuring points, 20,000 parameter settings are required. With so many measuring points, incorrect settings are almost inevitable.

This problem has been known in metrology for decades and has been addressed in various ways so far. There are three principal solutions:

### Solution a

The sensors include memory chips which have stored therein the individual sensor parameters. These so-called Transducer Electronic Data Sheets (TEDS) contain all required parameter data. The measuring amplifier is designed in such a way as to be able to read out this parameter data and then adjust itself to the optimum measuring accuracy. This process of individually adapting the measurement amplifier channel to a sensor is called parameterization. TEDS are integrated either in the sensor cable or in the sensor connector or on the sensor carrier, as shown in document U.S. Pat. No. 7,856,888 B2. TEDS are based on the IEEE 1451.4 standard, which is applied worldwide. The advantage of a sensor equipped with a TEDS resides therefore in the fact that the sensor with its individual characteristics can be automatically detected by a measuring amplifier. This eliminates the need for manual Input of the various sensor parameters on the measuring amplifier.

### Solution b

When manufacturing the sensors, an attempt is made to perfect the manufacturing technology in such a way that all sensors have approximately the same parameters. This is possible for some sensor types, but not for other sensor types. In most cases, it is then not possible when particularly high demands are placed on the measurement accuracy, such as, e.g., in the case of force measurement with strain gauges.

### Solution c

After their manufacture, the sensors are classified by various test steps and subdivided into groups so that each group contains sensors with approximately same parameters. However, this solution is rarely suitable for sensors with more than two parameters.

Accordingly, for solutions b and c, it is not necessary to enter the sensor parameters individually at the measuring amplifier channel.

Especially for accurate measurements and when the sensor has multiple parameters, the use of TEDS has become widely accepted.

However, there are also very special and very rare measurement tasks for which no practicable solutions exist yet.

Strain gauges are, e.g., cost-effective mass-produced items that are not coupled with a TEDS for the following reasons: The manufacturing costs of a TEDS can become higher than the manufacturing costs of the strain gauge, because storing the individual sensor parameters on the TEDS also Involves considerable effort. The same applies to certain thermocouples or other sensors that are also used without TEDS.

The group of strain gauges represents somewhat of an exception among mass sensors. Strain gauges are almost always used to perform accurate measurements. However, this requires setting the individual parameters of each strain gauge by hand on the measuring amplifier channel. There is, however, no manufacturing technology that can produce strain gauges with TEDS on a large scale, because most strain measurements do not require TEDS.

For a better understanding of the problem, the following is a concrete description of how a strain gauge is installed and parameterized.

The strain gauge is a thin plastic film with meander-shaped conductor tracks and has an edge length of, e.g., 10 mm. The strain gauge is bonded onto the measurement object, e.g. to a leaf spring of steel. When the leaf spring is deformed, the material strain on the surface of the leaf spring also changes. This strain is transferred to the strain gauge, causing its ohmic resistance to change. This change in resistance is proportional to the strain. The ohmic resistance is measured with the measuring amplifier, to which the strain gauge is electrically connected via a measuring cable.

The parameterization of the strain gauge is explained using the example of one of several parameters: One of the most important parameters of a strain gauge is its strain sensitivity and is called strain factor. The strain factor is the ratio of the change in resistance to the change in length that occurs when the measurement object is stretched. As already explained, it is not possible for manufacturing reasons to manufacture strain gauges with absolutely the same strain factor. Therefore, the manufacturer supplies for each strain gauge a data sheet which contains the parameters determined by the manufacturer.

This data sheet is a sheet of paper. During parameterization, the measuring technician reads the parameters from this sheet and sets them manually on the measurement amplifier channel. Since in many cases there are less than, e.g., 10 measuring points, this manual input of the parameters has been common practice for decades. Moreover, with such a small number of measuring cables, it is possible to connect each measuring cable to the correct amplifier channel without encountering a mix-up.

However, in a measurement situation with very many and spatially widely distributed sensor measuring points, completely new problems arise which could not be solved satisfactorily up to now. In other words, this cumbersome procedure has so far also been used for very many and spatially widely distributed sensor measuring points. Oftentimes, the measuring points are so far apart that two measuring technicians have to communicate with each other via radio communication. The first measuring technician is at the location of the measurement point and has the data sheet, which contains the numbered measurement point and the parameters of the corresponding strain gauge. The first measuring technician provides this information via radio communication to the second measuring technician, who sets the parameters by hand on the measuring amplifier, which is, e.g., 800 meters away.

As already mentioned, a correct overall measurement result can only be achieved when all cables are actually connected correctly and all measuring channels are parameterized without errors. Even a single mixed-up cable or a parameter accidentally read incorrectly from the data sheet or an incorrectly set parameter can lead to an unusable overall measurement result. With a high number of measuring points, many numbers must inevitably be read from the data sheets, transmitted via radio communication and set on the measuring amplifier. This leads to an exponentially high error rate. As a consequence, the effort required to avoid these errors also increases exponentially.

Since the use of TEDS is out of the question for the reasons explained above, it requires extreme control effort up to now to prevent the mix-up of cables and the Incorrect entry of parameters.

In this respect, the object of the invention is to provide a measurement technique with which the installation and operation of a measuring assembly with spatially widely distributed sensor measuring points can be carried out absolutely error-free and with little economic costs.

This object is attained with a method according to patent claim 1.

The method for the installation and operation of a measuring assembly with spatially widely distributed sensor measuring points includes the following method steps:
a. professionally attaching the sensors to the measurement object so that a proper measurement can be carried out,
b. connecting measuring cables to the electrical contact points of the sensors,
c. connecting each measuring cable to a respective measuring amplifier channel, wherein the sequence can be disregarded,
d. checking whether each of all measuring cables is connected to a corresponding measuring amplifier channel and the measuring instrument indicates a predetermined measuring signal for each measuring channel, which measuring signal confirms the basic function of the measuring chain “sensor-channel-measuring-instrument”,
e. acquiring the parameterization data from the data sheet belonging to the respective sensor using an acquisition device, with the parameterization data being temporarily stored as a data packet in the acquisition device,
f. feeding the parameterization data packet into the measuring cable end to which the sensor is connected or directly into the sensor, with the feed capable of being realized, e.g., inductively or mechanically,
g. when the measuring amplifier, i.e. the respective measuring channel, has received all the information required for identification and parameterization, the measuring amplifier generates a confirmation signal. The confirmation signal is sent back to the sensor and received there by a receiving device. The receiving device confirms the error-free parameterization of the sensor to the measuring technician at the sensor location optically or acoustically or in another way, such as, e.g., by vibration.

The confirmation signal can be sent back via the measuring cable. However, it is also possible to send the confirmation signal via another information channel. The confirmation signal is only sent when the parameterization of the sensor could be completed successfully.
h. Repetition of the steps e, f and g until all measuring amplifier channels are parameterized.

These process steps a to h achieve the desired results:

Use of conventional, cost-efficient sensors without TEDS and elimination of setting and mix-up errors during parameterization, completely independent of the number of measuring points, which can be of any magnitude.

Advantageous or particular refinements of the invention are set forth in claims 2 to 5.

The invention is described in more detail hereinafter with reference to schematic drawings:

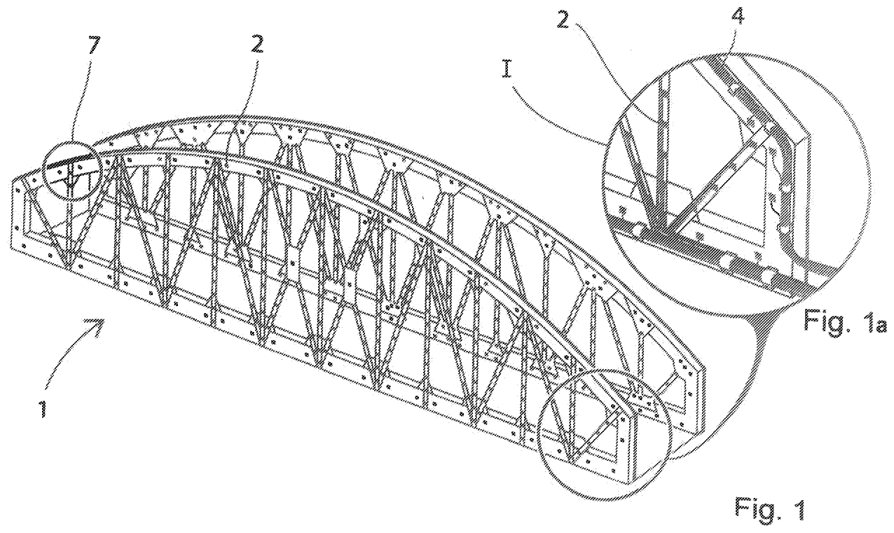

FIG. 1 shows a bridge having mounted thereon a multitude of strain gauge sensors as measurement object.

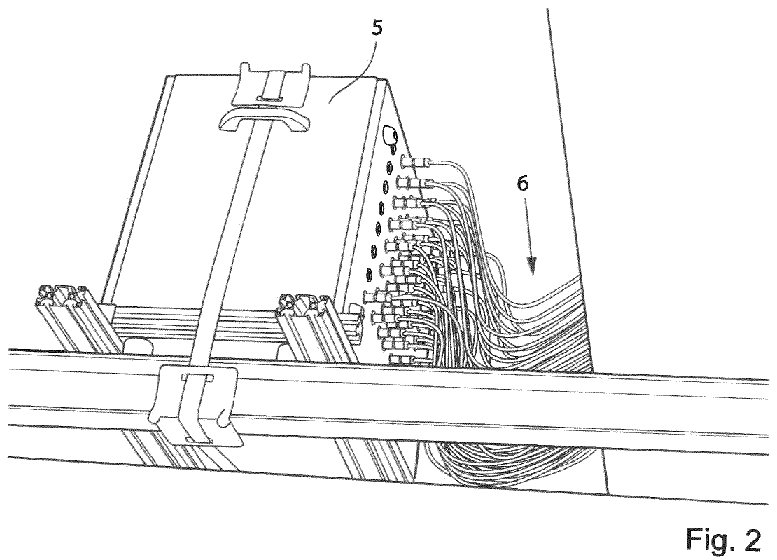

FIG. 2 shows a part of the measuring amplifier with a multitude of measuring cables.

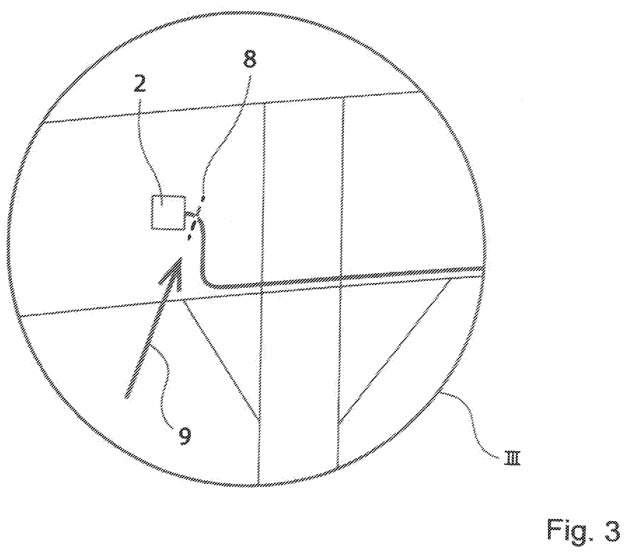

FIG. 3 shows an enlarged detailed view of a measuring point.

### LIST OF REFERENCE SIGNS

1—measurement object
2—sensor
3—enlarged cutaway of the measurement object
4—cable harnesses
5—measuring amplifier
6—measuring cable
7—measuring point on an enlarged scale
8—feed-in point
9—feed-in point of the parameterization signals

FIG. 1 shows a steel bridge 1 having mounted thereon a multitude of strain gauges 2. The enlarged view 3 shows that each strain gauge 2 is connected to the measuring amplifier 5 via a separate cable 6 and that the cables 6 are bundled to form cable harnesses 4. Due to the multitude of strain gauge sensors 2, it is apparent that the installation effort for the measuring assembly is very high. Accordingly, faulty measurements are to be avoided,

FIG. 2 shows a part of the measuring amplifier 5 with a plurality of measuring cables 6. Since the two ends of each measuring cable 6 are far apart from one another, it can evidently happen that the connector of a cable 6 is plugged into a wrong socket of the measuring amplifier 5 without noticing the mix-up of the measuring cables 6. It is clear to the measuring technician that this will render the overall measurement result unusable. This risk is eliminated by the invention.

FIG. 3 shows a view 7 of a measuring point with a strain gauge sensor 2. Arrow 9 points to the feed-in point 8, at which the parameterization data is fed for parameterization via a feed device. The parameterization data is then forwarded to a measuring amplifier channel. The feed device can be, e.g., an inductive device with which the data packet with the parameterization data is fed into the electrical connection line of the sensor and sent to the measuring amplifier channel.

The following describes the procedure for the installation and operation of a measuring assembly with spatially widely distributed sensor measuring points:
a. Initially, the sensors 2 are attached to the measurement object 1 in a metrologically correct manner. This means that there is a proper way of attachment for each type of sensor.
b. Connecting measuring cables 6 to the attached sensors 2.
c. Connecting each measuring cable 6 to a respective measuring amplifier channel, whereby the sequence can be disregarded. This step is a significant improvement of this method.
d. Checking whether all measuring cables 6 are connected to the measuring amplifier channels, respectively. Since the number of sensors 2 is known, the number of measuring cables 6 is also known automatically. At the same time, it is checked whether the measuring amplifier displays a predetermined measuring signal for each measuring channel. This means that a measuring technician knows the average magnitude of a measurement signal in the operating state of the sensor even without parameterization.
e. Scanning with a scanning device the data packet with the parameterization data from the paper data sheet belonging to the respective sensor. The parameterization data can be contained, e.g., in a QR code that can be read with a QR code reader.
f. When the scanned parameterization data is temporarily stored in the data acquisition device, the data packet belonging to the respective sensor 2 is fed into the measuring cable of this sensor 2 by means of a feed-in device. Feeding of the data packet can be implemented, e.g., inductively or optically or mechanically. The type of feed-in is dependent on the sensor type. Usually, an inductive feed-in is used when strain gauges or thermocouples are involved. However, measuring points with strain gauges can also be subjected to mechanical vibrations in which the parameterization data are modulated. This is possible, e.g., with an electromagnetically operating vibrator having a vibrating element which is placed directly upon the strain gauge.
g. When the measuring amplifier, i.e. the respective measuring channel, has received all signals of the respective data packet required for identification and parameterization, the measuring amplifier generates a confirmation signal which can be received by a receiving device. The confirmation signal is preferably sent back via the measuring cable and received at the feed-in point. The confirmation signal is sent only when the parameterization of the sensor has been successfully completed. It is, however, also possible to use an external transmission channel for transmitting the confirmation signal. The confirmation signal can preferably be output by the feed-in device, i.e. the data acquisition device, the feed-in device and the receiving device for the confirmation signal can be arranged in a common housing.
h. Repetition of the steps e, f and g until all measuring amplifier channels are parameterized.

The data packet includes at least the following data:
Parameterization data of the sensor which are printed on the paper data sheet of the respective sensor, e.g. as a scannable QR code, and
optionally location-related data, which allow an automatic association of the sensor to the location or position on the measurement object. For example, the additional use of GPS data can be used to detect where the sensor is located on a bridge. For this purpose, it is suitable to also integrate the GPS receiver into the housing of the feed-in device.

With this method, the object of the invention described above is attained.

What is claimed is:

1.-5. (canceled)

6. A method for installing and operating a measuring assembly with spatially widely distributed sensor measuring points, using sensors which are devoid of any TEDS, the method comprising:
a. attaching the sensors to a measurement object;
b. connecting measuring cables to the sensors in one-to-one correspondence;
c. connecting the measuring cables to measuring amplifier channels of a measuring amplifier in one-to-one correspondence;
d. checking whether each of the measuring cables is connected and the measuring amplifier indicates a measuring signal for each of the measuring amplifier channels;
e. acquiring parameterization data from a data sheet belonging to a corresponding one of the sensors using an acquisition device;
f. feeding the parameterization data into a measuring cable end to which the corresponding one of the sensors is connected or directly into the corresponding one of the sensors;
g. when the measuring channels have received the measuring signals required for identification and parameterization of the corresponding ones of the sensors, the measuring amplifier generating a confirmation signal and confirming to a measuring technician at a sensor location a proper parametrization of the sensor; and
h. repeating steps e, f, and g, until all measuring amplifier channels have been parametrized.

7. The method of claim 6, wherein the confirmation signal in step g is transmitted via a corresponding one of the measuring cables.

8. The method of claim 6, wherein the confirmation signal in step g is not sent via a corresponding one of the measuring cables, but via an information channel.

9. The method of claim 6, wherein each of the sensors is a strain gauge.

10. The method of claim 6, wherein each of the sensors is a thermocouple.
